(19) United States
(12) Patent Application Publication
(10) Pub. No.: US 2025/0308766 A1
(43) Pub. Date: Oct. 2, 2025

(54) ELECTRONIC COMPONENT

(71) Applicant: TDK Corporation, Tokyo (JP)

(72) Inventor: Aozora KAWASAKI, Tokyo (JP)

(73) Assignee: TDK Corporation, Tokyo (JP)

(21) Appl. No.: 19/040,875

(22) Filed: Jan. 30, 2025

(30) Foreign Application Priority Data
Mar. 28, 2024 (JP) 2024-054624

(51) Int. Cl. H01F 27/40; H01F 27/29; H01F 27/36; H03H 7/01

(52) U.S. Cl. CPC H01F 27/40; H01F 27/292; H01F 27/363; H03H 7/0115

(57) ABSTRACT

An electronic component includes: an element body; a first inductor group including a fourth inductor constituting a first filter having a first pass band; a second inductor group including a seventh inductor constituting a second filter having a second pass band; a first shield disposed between the fourth inductor and the seventh inductor when viewed from a second direction and extending in a third direction orthogonal to a first direction in which the first inductor group and the second inductor group are arranged; and a second shield extending in the first direction, in which the second shield is disposed in a region outside the first inductor group when viewed from the second direction.

### CROSS-REFERENCE TO RELATED APPLICATION

This application is based upon and claims the benefit of priority from Japanese Patent Application No. 2024-054624, filed on Mar. 28, 2024, the entire contents of which are incorporated herein by reference.

### TECHNICAL FIELD

The present disclosure relates to an electronic component.

### BACKGROUND

Japanese Unexamined Patent Publication No. 2006-60747 discloses an electronic component including a piezoelectric substrate, a plurality of surface acoustic wave filter patterns provided on a surface of the piezoelectric substrate, and a shield electrode provided between opposing surface acoustic wave filter patterns so as to extend upward from the surface of the piezoelectric substrate.

### SUMMARY

In a configuration in which a plurality of filters are provided in the electronic component, even in a case where isolation is secured by arranging a shield between the filters, wraparound of magnetic flux can occur between the filters. Thus, there is a possibility that loss occurs due to coupling of inductors between the filters, and characteristics of the electronic component are deteriorated.

An object of one aspect of the present disclosure is to provide an electronic component capable of improving the characteristics of the electronic component.

(1) An electronic component according to one aspect of the present disclosure includes: an element body formed by laminating a plurality of insulator layers; a first conductor group including a first inductor constituting a first filter having a first pass band; a second conductor group including a second inductor constituting a second filter having a second pass band; a first shield disposed between the first inductor and the second inductor when viewed from a lamination direction of the plurality of insulator layers and extending in another direction orthogonal to one direction in which the first conductor group and the second conductor group are arranged; and a second shield extending in the one direction, in which the second shield is disposed in a region outside the first conductor group when viewed from the lamination direction.

The electronic component according to the one aspect of the present disclosure includes the first shield and the second shield. The first shield is disposed between the first inductor and the second inductor, and extends in the other direction. Thus, in the electronic component, isolation between the first inductor (first filter) and the second inductor (second filter) can be secured. Further, in the electronic component, the second shield extends in the one direction and is disposed in the region outside the first conductor group when viewed from the lamination direction. Thus, in the electronic component, the second shield can suppress the wraparound of the magnetic flux between the first inductor and the second inductor. Therefore, in the electronic component, the isolation between the first filter and the second filter can be improved. As a result, the characteristics of the electronic component can be improved.

(2) In the electronic component of the above (1), the first shield and the second shield may be connected to each other. In this configuration, the isolation between the first filter and the second filter can be further improved.

(3) In the electronic component of the above (1) or (2), an axial direction of the first inductor and an axial direction of the second inductor may intersect each other when viewed from the lamination direction. In this configuration, the wraparound of the magnetic flux can occur between the first inductor and the second inductor. Therefore, in a configuration in which the axial direction of the first inductor and the axial direction of the second inductor intersect each other, it is particularly effective to provide the second shield for improving the isolation.

(4) In the electronic component of the above (3), the axial direction of the second inductor may intersect an extending direction of the first shield when viewed from the lamination direction. In this configuration, the isolation between the first filter and the second filter can be improved.

(5) In the electronic component of the above (4), the axial direction of the first inductor may intersect an extending direction of the second shield when viewed from the lamination direction. In this configuration, the isolation between the first filter and the second filter can be improved.

(6) In the electronic component according to any one of the above (1) to (5), the second shield may extend along an outer surface of the element body. In this configuration, the wraparound of the magnetic flux can be effectively suppressed.

(7) In the electronic component according to any one of the above (1) to (6), the second shield may overlap at least a part of the first inductor or the second inductor when viewed from the other direction. In this configuration, the wraparound of the magnetic flux can be effectively suppressed.

(8) In the electronic component according to any one of the above (1) to (7), heights of the first shield and the second shield in the lamination direction may be the same as a height of the first inductor in the lamination direction. In this configuration, the isolation between the first filter and the second filter can be further improved.

(9) An electronic component according to one aspect of the present disclosure includes: an element body formed by laminating a plurality of insulator layers; a first conductor group including a first inductor constituting a first filter having a first pass band; a second conductor group including a second inductor constituting a second filter having a second pass band; and a shield extending in one direction in which the first conductor group and the second conductor group are arranged when viewed from a lamination direction of the plurality of insulator layers.

The electronic component according to the one aspect of the present disclosure includes the shield extending in the one direction in which the first conductor group and the second conductor group are arranged when viewed from the lamination direction. Thus, in the electronic component, the shield can suppress the wraparound of the magnetic flux between the first inductor and the second inductor. Therefore, in the electronic component, the isolation between the first filter and the second filter can be improved. As a result, the characteristics of the electronic component can be improved.

(10) In the electronic component of the above (9), each of the first inductor and the second inductor may be disposed at a position close to one side surface of the element body, and the shield may be disposed between the first inductor and the one side surface. In this configuration, the wraparound of the magnetic flux can be effectively suppressed.

(11) In the electronic component according to the above (9) or (10), an axial direction of the first inductor and an axial direction of the second inductor may intersect each other. In this configuration, the wraparound of the magnetic flux can occur between the first inductor and the second inductor. Therefore, in a configuration in which the axial direction of the first inductor and the axial direction of the second inductor intersect each other, it is particularly effective to provide the shield for improving the isolation.

(12) In the electronic component of the above (11), the axial direction of the first inductor may intersect an extending direction of the shield. In this configuration, the isolation between the first filter and the second filter can be improved.

(13) In the electronic component according to any one of the above (9) to (12), the shield may overlap at least a part of the first inductor or the second inductor when viewed from another direction orthogonal to the one direction in which the first conductor group and the second conductor group are arranged. In this configuration, the wraparound of the magnetic flux can be effectively suppressed.

(14) In the electronic component according to any one of the above (9) to (13), the shield may be disposed over a region where the first conductor group is disposed and a region where the second conductor group is disposed. In this configuration, the wraparound of the magnetic flux can be effectively suppressed.

According to one aspect of the present disclosure, the characteristics of the electronic component can be improved.

### BRIEF DESCRIPTION OF THE DRAWINGS

FIG. 1 is a perspective view of an electronic component according to a first embodiment;

FIG. 2A is a view of an element body as viewed from one main surface side, and FIG. 2B is a view of the element body as viewed from the other main surface side;

FIG. 3 is an equivalent circuit diagram of the electronic component illustrated in FIG. 1;

FIG. 4 is a perspective view of the electronic component according to a second embodiment;

FIG. 5 is a perspective view of the electronic component according to a third embodiment; and

FIG. 6 is a perspective view of the electronic component according to a fourth embodiment.

### DETAILED DESCRIPTION

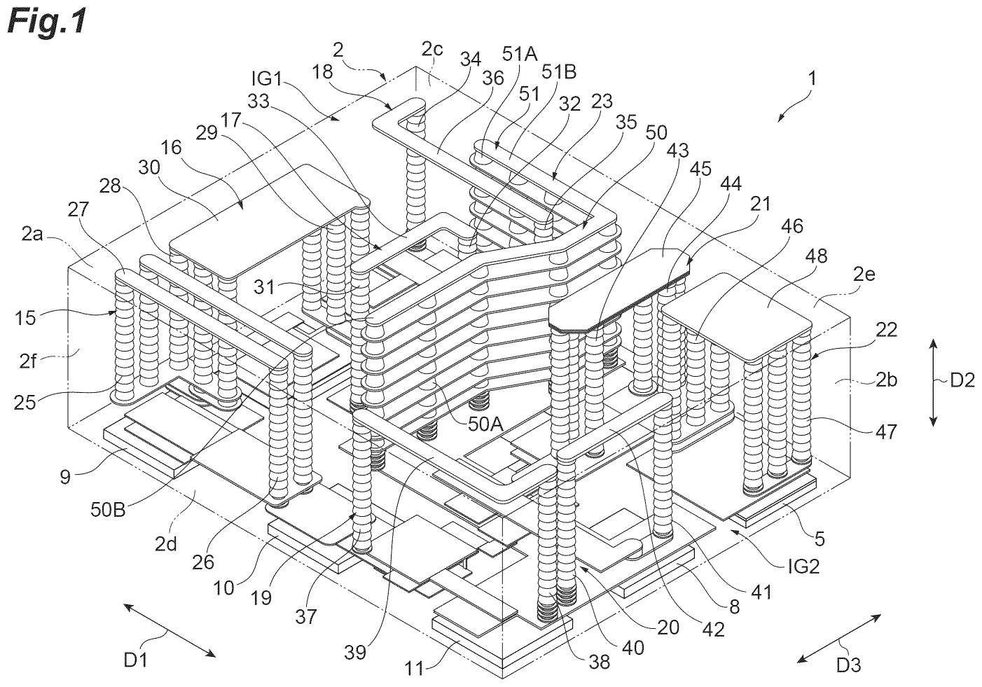

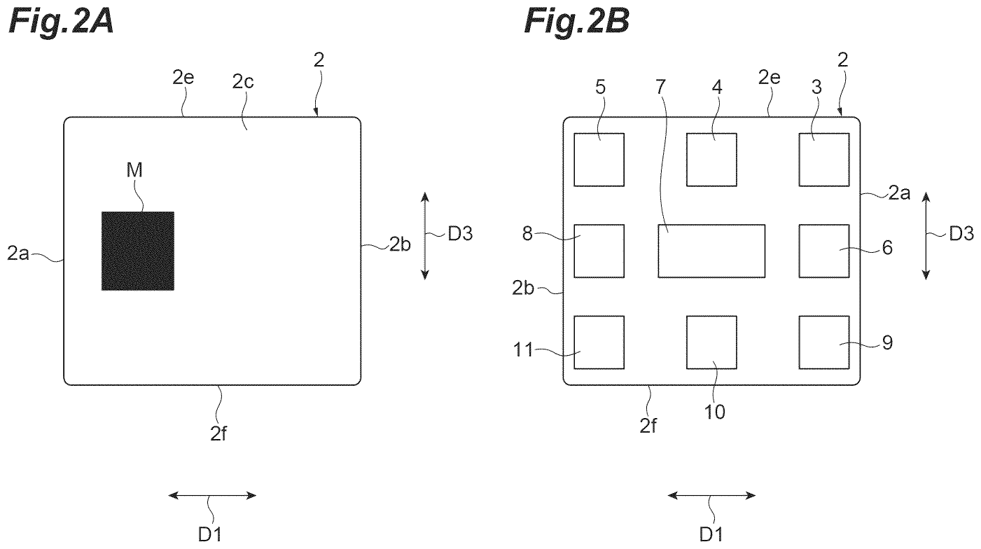

Hereinafter, preferred embodiments of the present disclosure will be described in detail with reference to the accompanying drawings. Note that in the description of the drawings, the same or corresponding elements are denoted by the same reference numerals, and redundant description thereof will be omitted.

[First Embodiment] FIG. 1 is a perspective view illustrating an electronic component according to a first embodiment. FIG. 2A is a view of an element body as viewed from one main surface side, and FIG. 2B is a view of the element body as viewed from the other main surface side. As illustrated in FIGS. 1, 2A, and 2B, an electronic component 1 includes an element body 2, a first terminal electrode 3, a second terminal electrode 4, a third terminal electrode 5, a fourth terminal electrode 6, a fifth terminal electrode 7, a sixth terminal electrode 8, a seventh terminal electrode 9, an eighth terminal electrode 10, and a ninth terminal electrode 11. In FIG. 1, the element body 2 is indicated by a two-dot chain line.

The element body 2 has a rectangular parallelepiped shape. The rectangular parallelepiped shape includes a rectangular parallelepiped shape in which corners and ridges are chamfered, and a rectangular parallelepiped shape in which corners and ridges are rounded. The element body 2 has, as outer surfaces, a pair of end surfaces 2a and 2b, a pair of main surfaces 2c and 2d, and a pair of side surfaces 2e and 2f. The end surfaces 2a and 2b are opposed to each other. The main surfaces 2c and 2d are opposed to each other. The side surfaces 2e and 2f are opposed to each other. Hereinafter, an opposing direction of the end surfaces 2a and 2b is referred to as a first direction (one direction) D1, an opposing direction of the main surfaces 2c and 2d is referred to as a second direction D2, and an opposing direction of the side surfaces 2e and 2f is referred to as a third direction (another direction) D3. The first direction D1, the second direction D2, and the third direction D3 are substantially orthogonal to each other.

The end surfaces 2a and 2b extend in the second direction D2 so as to connect the main surfaces 2c and 2d. The end surfaces 2a and 2b also extend in the third direction D3 so as to connect the side surfaces 2e and 2f. The main surfaces 2c and 2d extend in the first direction D1 so as to connect the end surfaces 2a and 2b. The main surfaces 2c and 2d also extend in the third direction D3 so as to connect the side surfaces 2e and 2f. The side surfaces 2e and 2f extend in the first direction D1 so as to connect the end surfaces 2a and 2b. The side surfaces 2e and 2f also extend in the second direction D2 so as to connect the main surfaces 2c and 2d.

The main surface 2d is a mounting surface, and is a surface facing another electronic device, for example, when the electronic component 1 is mounted on another electronic device (not illustrated, for example, a circuit substrate or a laminated electronic component). The end surfaces 2a and 2b are surfaces continuous from the mounting surface (that is, the main surface 2d). As illustrated in FIG. 2A, a mark M is provided on the main surface 2c. The mark M indicates an orientation or a direction of the electronic component 1. Note that the mark M may not be provided.

A length of the element body 2 in the first direction D1 is longer than that of the element body 2 in the second direction D2 and that of the element body 2 in the third direction D3. The length of the element body 2 in the second direction D2 is shorter than that of the element body 2 in the third direction D3. That is, in the present embodiment, the end surfaces 2a and 2b, the main surfaces 2c and 2d, and the side surfaces 2e and 2f each have a rectangular shape. The length of the element body 2 in the second direction D2 may be equal to that of the element body 2 in the third direction D3, or may be longer than that of the element body 2 in the third direction D3.

Note that in the present embodiment, “equal” may be equal to a value including a slight difference or a manufacturing error in a preset range in addition to being equal. For example, if a plurality of values are included within a range of ±5% of an average value of the plurality of values, the plurality of values are defined to be equal.

The element body 2 is formed by laminating a plurality of insulator layers (not illustrated) in the second direction D2. That is, a lamination direction of the element body 2 is the second direction D2. In the actual element body 2, the plurality of insulator layers may be integrated to such an extent that boundaries between the layers cannot be visually recognized, or may be integrated so that the boundaries between the layers can be visually recognized.

The insulator layer includes, for example, a sintered body of a ceramic green sheet containing a dielectric material. The dielectric material includes, for example, at least one selected from a BaTiO₃-based material, a Ba(Ti,Zr)O₃-based material, a (Ba,Ca)TiO₃-based material, a glass material, or an alumina material.

Each of the first terminal electrode 3, the second terminal electrode 4, the third terminal electrode 5, the fourth terminal electrode 6, the fifth terminal electrode 7, the sixth terminal electrode 8, the seventh terminal electrode 9, the eighth terminal electrode 10, and the ninth terminal electrode 11 is provided on the element body 2. Each of the first terminal electrode 3, the second terminal electrode 4, the third terminal electrode 5, the fourth terminal electrode 6, the fifth terminal electrode 7, the sixth terminal electrode 8, the seventh terminal electrode 9, the eighth terminal electrode 10, and the ninth terminal electrode 11 is disposed on the main surface 2d of the element body 2.

Each of the first terminal electrode 3, the second terminal electrode 4, the third terminal electrode 5, the fourth terminal electrode 6, the fifth terminal electrode 7, the sixth terminal electrode 8, the seventh terminal electrode 9, the eighth terminal electrode 10, and the ninth terminal electrode 11 has a rectangular shape. Each of the first terminal electrode 3, the second terminal electrode 4, the third terminal electrode 5, the fourth terminal electrode 6, the fifth terminal electrode 7, the sixth terminal electrode 8, the seventh terminal electrode 9, the eighth terminal electrode 10, and the ninth terminal electrode 11 is disposed such that each side extends in the first direction D1 or in the third direction D3.

The first terminal electrode 3, the second terminal electrode 4, the third terminal electrode 5, the fourth terminal electrode 6, the fifth terminal electrode 7, the sixth terminal electrode 8, the seventh terminal electrode 9, the eighth terminal electrode 10, and the ninth terminal electrode 11 protrude from the main surface 2d. That is, in the present embodiment, surfaces of the first terminal electrode 3, the second terminal electrode 4, the third terminal electrode 5, the fourth terminal electrode 6, the fifth terminal electrode 7, the sixth terminal electrode 8, the seventh terminal electrode 9, the eighth terminal electrode 10, and the ninth terminal electrode 11 are not flush with the main surface 2d. The first terminal electrode 3, the second terminal electrode 4, the third terminal electrode 5, the fourth terminal electrode 6, the fifth terminal electrode 7, the sixth terminal electrode 8, the seventh terminal electrode 9, the eighth terminal electrode 10, and the ninth terminal electrode 11 include a conductive material (for example, Cu).

Each of the first terminal electrode 3, the second terminal electrode 4, the third terminal electrode 5, the fourth terminal electrode 6, the fifth terminal electrode 7, the sixth terminal electrode 8, the seventh terminal electrode 9, the eighth terminal electrode 10, and the ninth terminal electrode 11 may be provided with a plating layer (not illustrated) containing, for example, Ni, Sn, Au, or the like by electrolytic plating or electroless plating. The plating layer may include, for example, a Ni plating film containing Ni and covering the first terminal electrode 3, the second terminal electrode 4, the third terminal electrode 5, the fourth terminal electrode 6, the fifth terminal electrode 7, the sixth terminal electrode 8, the seventh terminal electrode 9, the eighth terminal electrode 10, and the ninth terminal electrode 11, and an Au plating film containing Au and covering the Ni plating film.

As illustrated in FIG. 1, in the electronic component 1, a first inductor 15, a second inductor 16, a third inductor 17, a fourth inductor (first inductor) 18, a fifth inductor 19, a sixth inductor 20, a seventh inductor (second inductor) 21, an eighth inductor 22, and a shield 23 are arranged in the element body 2. In the electronic component 1, a plurality of capacitor conductors constituting capacitors C1 to C25 (described later) are also arranged in the element body 2. Each inductor and capacitor conductor constitute a resonator.

The first inductor 15, the second inductor 16, the third inductor 17, and the fourth inductor 18 are arranged in a region on the end surface 2a side from a center in the first direction D1 in the element body 2. The first inductor 15, the second inductor 16, the third inductor 17, and the fourth inductor 18 constitute a first inductor group (first conductor group) IG1.

The fifth inductor 19, the sixth inductor 20, the seventh inductor 21, and the eighth inductor 22 are arranged in a region on the end surface 2b side from the center in the first direction D1 in the element body 2. The fifth inductor 19, the sixth inductor 20, the seventh inductor 21, and the eighth inductor 22 constitute a second inductor group (second conductor group) IG2. The first inductor group IG1 and the second inductor group IG2 are arranged side by side in the first direction D1.

The first inductor 15 is disposed at a position close to the end surface 2a and close to the side surface 2f in the element body 2. The first inductor 15 is configured by including an inductor conductor 25, an inductor conductor 26, and an inductor conductor 27. In the present embodiment, the first inductor 15 includes two inductor conductors 25, two inductor conductors 26, and two inductor conductors 27. An axial direction of the first inductor 15 is the third direction D3.

The inductor conductor 25 extends in the second direction D2. The inductor conductor 25 can include a plurality of via conductors. The inductor conductor 26 extends in the second direction D2. The inductor conductor 26 can include a plurality of via conductors. The inductor conductor 25 and the inductor conductor 26 are arranged at a predetermined interval in the first direction D1.

The inductor conductor 27 electrically connects the inductor conductor 25 and the inductor conductor 26. The inductor conductor 27 has a substantially rectangular shape (long shape). The inductor conductor 27 is disposed over one end (end on the main surface 2c side) of the inductor conductor 25 in the second direction D2 and one end (end on the main surface 2c side) of the inductor conductor 26 in the second direction D2. The inductor conductor 27 is stretched between the inductor conductor 25 and the inductor conductor 26. The inductor conductor 27 is disposed in the first direction D1. That is, the inductor conductor 27 extends in the first direction D1. The inductor conductor 27 may include one conductor or may include a plurality of (for example, two) conductors.

The second inductor 16 is disposed at a position close to the end surface 2a of the element body 2. The second inductor 16 is configured by including an inductor conductor 28, an inductor conductor 29, and an inductor conductor 30. In the present embodiment, the second inductor 16 includes three inductor conductors 28, three inductor conductors 29, and one inductor conductor 30. An axial direction of the second inductor 16 is the first direction D1.

The inductor conductor 28 extends in the second direction D2. The inductor conductor 28 can include a plurality of via conductors. The inductor conductor 29 extends in the second direction D2. The inductor conductor 29 can include a plurality of via conductors. The inductor conductor 28 and the inductor conductor 29 are arranged at a predetermined interval in the third direction D3.

The inductor conductor 30 electrically connects the inductor conductor 28 and the inductor conductor 29. The inductor conductor 30 has a substantially rectangular shape (long shape). The inductor conductor 30 is disposed over one end of the inductor conductor 28 in the second direction D2 and one end of the inductor conductor 29 in the second direction D2. The inductor conductor 30 is stretched between the inductor conductor 28 and the inductor conductor 29. The inductor conductor 30 is disposed in the third direction D3. That is, the inductor conductor 30 extends in the third direction D3. The inductor conductor 30 may include one conductor or may include a plurality of (for example, two) conductors.

The third inductor 17 is disposed at a position close to a central portion of the element body 2. The third inductor 17 is configured by including an inductor conductor 31, an inductor conductor 32, and an inductor conductor 33. In the present embodiment, the third inductor 17 includes one inductor conductor 31, one inductor conductor 32, and one inductor conductor 33. An axial direction of the third inductor 17 is the first direction D1.

The inductor conductor 31 extends in the second direction D2. The inductor conductor 31 can include a plurality of via conductors. The inductor conductor 32 extends in the second direction D2. The inductor conductor 32 can include a plurality of via conductors. The inductor conductor 31 and the inductor conductor 32 are arranged at a predetermined interval in the third direction D3.

The inductor conductor 33 electrically connects the inductor conductor 31 and the inductor conductor 32. The inductor conductor 33 has a substantially L-shape. The inductor conductor 33 is disposed over one end of the inductor conductor 31 in the second direction D2 and one end of the inductor conductor 32 in the second direction D2. The inductor conductor 33 is stretched between the inductor conductor 31 and the inductor conductor 32.

The inductor conductor 33 has an L-shape as described above, and has a portion extending in the first direction D1 and a portion extending in the third direction D3. In the present embodiment, when the conductor has a plurality of portions having different extending directions, an extending direction of a longer extending portion is defined as an extending direction of the conductor. In the inductor conductor 33, a portion extending in the third direction D3 is longer than a portion extending in the first direction D1. Therefore, in the present embodiment, the inductor conductor 33 extends in the third direction D3. The inductor conductor 33 may include one conductor or may include a plurality of (for example, two) conductors.

The fourth inductor 18 is disposed at a position close to the end surface 2a and close to the side surface (one side surface) 2e in the element body 2. The fourth inductor 18 is configured by including an inductor conductor 34, an inductor conductor 35, and an inductor conductor 36. In the present embodiment, the fourth inductor 18 includes one inductor conductor 34, one inductor conductor 35, and one inductor conductor 36. An axial direction of the fourth inductor 18 is the third direction D3.

The inductor conductor 34 extends in the second direction D2. The inductor conductor 34 can include a plurality of via conductors. The inductor conductor 35 extends in the second direction D2. The inductor conductor 35 can include a plurality of via conductors. The inductor conductor 34 and the inductor conductor 35 are arranged at a predetermined interval in the first direction D1.

The inductor conductor 36 electrically connects the inductor conductor 34 and the inductor conductor 35. The inductor conductor 36 has a substantially L-shape. The inductor conductor 36 is disposed over one end of the inductor conductor 34 in the second direction D2 and one end of the inductor conductor 35 in the second direction D2. The inductor conductor 36 is stretched between the inductor conductor 34 and the inductor conductor 35. The inductor conductor 36 is disposed in the first direction D1. The inductor conductor 36 extends in the first direction D1. The inductor conductor 36 may include one conductor or may include a plurality of (for example, two) conductors.

The fifth inductor 19 is disposed at a position close to the end surface 2b and close to the side surface 2f in the element body 2. The fifth inductor 19 is configured by including an inductor conductor 37, an inductor conductor 38, and an inductor conductor 39. In the present embodiment, the fifth inductor 19 includes one inductor conductor 37, one inductor conductor 38, and one inductor conductor 39. An axial direction of the fifth inductor 19 is the third direction D3.

The inductor conductor 37 extends in the second direction D2. The inductor conductor 37 can include a plurality of via conductors. The inductor conductor 38 extends in the second direction D2. The inductor conductor 38 can include a plurality of via conductors. The inductor conductor 37 and the inductor conductor 38 are arranged at a predetermined interval in the first direction D1.

The inductor conductor 39 electrically connects the inductor conductor 37 and the inductor conductor 38. The inductor conductor 39 has a substantially L-shape. The inductor conductor 39 is disposed over one end of the inductor conductor 37 in the second direction D2 and one end of the inductor conductor 38 in the second direction D2. The inductor conductor 39 is stretched between the inductor conductor 37 and the inductor conductor 38. The inductor conductor 39 is disposed in the first direction D1. The inductor conductor 39 extends in the first direction D1. The inductor conductor 39 may include one conductor or may include a plurality of (for example, two) conductors.

The sixth inductor 20 is disposed at a position close to the end surface 2b of the element body 2. The sixth inductor 20 is configured by including an inductor conductor 40, an inductor conductor 41, and an inductor conductor 42. In the present embodiment, the sixth inductor 20 includes one inductor conductor 40, one inductor conductor 41, and one inductor conductor 42. An axial direction of the sixth inductor 20 is the third direction D3.

The inductor conductor 40 extends in the second direction D2. The inductor conductor 40 can include a plurality of via conductors. The inductor conductor 41 extends in the second direction D2. The inductor conductor 41 can include a plurality of via conductors. The inductor conductor 40 and the inductor conductor 41 are arranged at a predetermined interval in the third direction D3.

The inductor conductor 42 electrically connects the inductor conductor 40 and the inductor conductor 41. The inductor conductor 42 has a substantially rectangular shape (long shape). The inductor conductor 42 is disposed over one end of the inductor conductor 40 in the second direction D2 and one end of the inductor conductor 41 in the second direction D2. The inductor conductor 42 is stretched between the inductor conductor 40 and the inductor conductor 41. The inductor conductor 42 is disposed in the third direction D3. That is, the inductor conductor 42 extends in the third direction D3. The inductor conductor 42 may include one conductor or may include a plurality of (for example, two) conductors.

The seventh inductor 21 is disposed at a position close to the center of the element body 2 in the first direction D1 and close to the side surface 2e. The seventh inductor 21 is configured by including an inductor conductor 43, an inductor conductor 44, and an inductor conductor 45. In the present embodiment, the seventh inductor 21 includes three inductor conductors 43, three inductor conductors 44, and one inductor conductor 45. An axial direction of the seventh inductor 21 is the first direction D1.

The inductor conductor 43 extends in the second direction D2. The inductor conductor 43 can include a plurality of via conductors. The inductor conductor 44 extends in the second direction D2. The inductor conductor 44 can include a plurality of via conductors. The inductor conductor 43 and the inductor conductor 44 are arranged at a predetermined interval in the third direction D3.

The inductor conductor 45 electrically connects the inductor conductor 43 and the inductor conductor 44. The inductor conductor 45 has a polygonal shape. The inductor conductor 35 is disposed over one end of the inductor conductor 43 in the second direction D2 and one end of the inductor conductor 44 in the second direction D2. The inductor conductor 45 is stretched between the inductor conductor 43 and the inductor conductor 44. The inductor conductor 45 is disposed in the third direction D3. That is, the inductor conductor 45 extends in the third direction D3. The inductor conductor 45 may include one conductor or may include a plurality of (for example, two) conductors.

The eighth inductor 22 is disposed at a position close to the end surface 2b and close to the side surface 2e in the element body 2. The eighth inductor 22 is configured by including an inductor conductor 46, an inductor conductor 47, and an inductor conductor 48. In the present embodiment, the eighth inductor 22 includes three inductor conductors 46, three inductor conductors 47, and one inductor conductor 48. An axial direction of the eighth inductor 22 is the third direction D3.

The inductor conductor 46 extends in the second direction D2. The inductor conductor 46 can include a plurality of via conductors. The inductor conductor 47 extends in the second direction D2. The inductor conductor 47 can include a plurality of via conductors. The inductor conductor 46 and the inductor conductor 47 are arranged at a predetermined interval in the first direction D1.

The inductor conductor 48 electrically connects the inductor conductor 46 and the inductor conductor 47. The inductor conductor 48 has a rectangular shape. The inductor conductor 48 is disposed over one end of the inductor conductor 46 in the second direction D2 and one end of the inductor conductor 47 in the second direction D2. The inductor conductor 48 is stretched between the inductor conductor 46 and the inductor conductor 47. The inductor conductor 48 is disposed in the first direction D1. That is, the inductor conductor 48 extends in the first direction D1. The inductor conductor 48 may include one conductor or may include a plurality of (for example, two) conductors.

The shield 23 shields magnetic flux between the first inductor group IG1 and the second inductor group IG2. The shield 23 is electrically connected to the second terminal electrode 4, the fifth terminal electrode 7, the sixth terminal electrode 8, and the ninth terminal electrode 11. A height of the shield 23 in the second direction D2 is the same as that of the first inductor 15, the second inductor 16, the third inductor 17, the fourth inductor 18, the fifth inductor 19, the sixth inductor 20, the seventh inductor 21, and the eighth inductor 22 in the second direction D2. That is, a height position of an end of the shield 23 on the main surface 2c side is the same as that of an end of each of the first inductor 15, the second inductor 16, the third inductor 17, the fourth inductor 18, the fifth inductor 19, the sixth inductor 20, the seventh inductor 21, and the eighth inductor 22 on the main surface 2c side.

The shield 23 is configured by including a first shield 50 and a second shield 51. In the present embodiment, the first shield 50 and the second shield 51 are electrically connected and integrally formed.

The first shield 50 is disposed between the first inductor group IG1 and the second inductor group IG2. The first shield 50 extends in the third direction D3. That is, the first shield 50 extends in the third direction D3 orthogonal to (intersecting) the first direction D1 in which the first inductor group IG1 and the second inductor group IG2 are arranged. In an example illustrated in FIG. 1, the first shield 50 has a bent portion when viewed from the second direction D2, but the first shield 50 may be linear. An extending direction of the first shield 50 is orthogonal to (intersects) the axial direction of the second inductor 16, the axial direction of the third inductor 17, the axial direction of the sixth inductor 20, and the axial direction of the seventh inductor 21.

In the present embodiment, the first shield 50 is disposed between the second inductor 16, the third inductor 17, and the fourth inductor 18 and the sixth inductor 20, the seventh inductor 21, and the eighth inductor 22 between the first inductor group IG1 and the second inductor group IG2. The first shield 50 is not disposed between the first inductor 15 and the fifth inductor 19.

The first shield 50 is constituted by a plurality of first conductors 50A and a plurality of first connection conductors 50B. In the present embodiment, five first conductors 50A are provided. The plurality of first conductors 50A have the same configuration and the same dimension. The plurality of first conductors 50A extend in the second direction D2. Each of the plurality of first conductors 50A can include a plurality of via conductors. The plurality of first conductors 50A are arranged at predetermined intervals. The predetermined interval is preferably small from the viewpoint of shielding property.

In the present embodiment, nine first connection conductors 50B are provided. The plurality of first connection conductors 50B have the same configuration and the same dimension. Each of the plurality of first connection conductors 50B electrically connects the first conductors 50A. The plurality of first connection conductors 50B are arranged at predetermined intervals in the second direction D2. The predetermined interval is preferably small from the viewpoint of shielding property. The plurality of first connection conductors 50B have a predetermined width when viewed from the second direction D2.

The second shield 51 is connected to one end (end on the side surface 2e side) of the first shield 50. The second shield 51 is disposed in a region outside the first inductor group IG1. The second shield 51 is disposed between the side surface 2e of the element body 2 and the fourth inductor 18. The second shield 51 is disposed at a position overlapping a part of the fourth inductor 18 when viewed from the third direction D3. The second shield 51 extends in the first direction D1. An extending direction of the second shield 51 is orthogonal to (intersects) the axial direction of the fourth inductor 18.

The second shield 51 is configured by including a plurality of second conductors 51A and a plurality of second connection conductors 51B. In the present embodiment, three second conductors 51A are provided. The plurality of second conductors 51A have the same configuration and the same dimension. The plurality of second conductors 51A extend in the second direction D2. Each of the plurality of second conductors 51A can include a plurality of via conductors. The plurality of second conductors 51A are arranged at predetermined intervals.

In the present embodiment, the second connection conductor 51B is formed integrally with the first connection conductor 50B. Nine second connection conductors 51B are provided. The plurality of second connection conductors 51B have the same configuration and the same dimension. Each of the plurality of second connection conductors 51B electrically connects the second conductors 51A. The plurality of second connection conductors 51B are arranged at predetermined intervals in the second direction D2. The plurality of second connection conductors 51B have a predetermined width when viewed from the second direction D2.

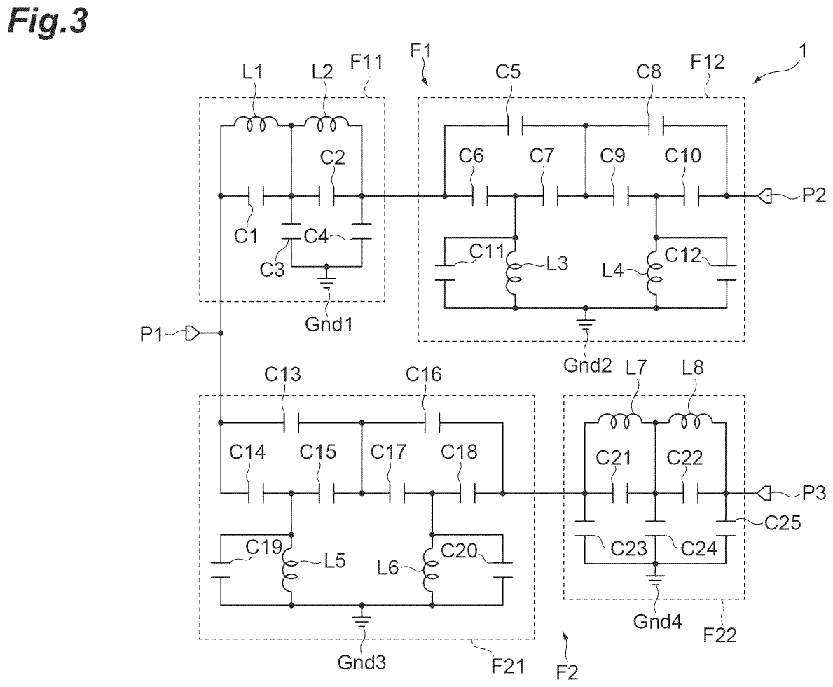

FIG. 3 is an equivalent circuit diagram of the electronic component 1 illustrated in FIG. 1. As illustrated in FIG. 3, the electronic component 1 includes a common port P1, a low port P2, a high port P3, a ground Gnd1, a ground Gnd2, a ground Gnd3, and a ground Gnd4.

The electronic component 1 includes an inductor L1, an inductor L2, an inductor L3, an inductor L4, an inductor L5, an inductor L6, an inductor L7, an inductor L8, a capacitor C1, a capacitor C2, a capacitor C3, a capacitor C4, a capacitor C5, a capacitor C6, a capacitor C7, a capacitor C8, a capacitor C9, a capacitor C10, a capacitor C11, a capacitor C12, a capacitor C13, a capacitor C14, a capacitor C15, a capacitor C16, a capacitor C17, a capacitor C18, a capacitor C19, a capacitor C20, a capacitor C21, a capacitor C22, a capacitor C23, a capacitor C24, and a capacitor C25.

The common port P1 includes the eighth terminal electrode 10. The low port P2 includes the first terminal electrode 3. The high port P3 includes the third terminal electrode 5. The ground Gnd1, the ground Gnd2, the ground Gnd3, and the ground Gnd4 include the second terminal electrode 4, the fourth terminal electrode 6, the fifth terminal electrode 7, the sixth terminal electrode 8, the seventh terminal electrode 9, and the ninth terminal electrode 11.

The electronic component 1 includes a first filter F1 and a second filter F2. The first filter F1 is configured to include a filter F11 and a filter F12. The first filter F1 has a first pass band. The first filter F1 allows a first signal having a frequency within a first frequency band to pass therethrough. One end of the first filter F1 is connected to the common port P1. The other end of the first filter F1 is connected to the low port P2.

The second filter F2 is configured to include a filter F21 and a filter F22. The second filter F2 has a second pass band. The second filter F2 allows a second signal having a frequency within a second frequency band to pass therethrough. One end of the second filter F2 is connected to the common port P1. The other end of the second filter F2 is connected to the high port P3.

The filter F11 includes the inductor L1, the inductor L2, the capacitor C1, the capacitor C2, the capacitor C3, and the capacitor C4. In the present embodiment, the filter F11 is a low-pass filter. The filter F12 includes the inductor L3, the inductor L4, the capacitor C5, the capacitor C6, the capacitor C7, the capacitor C8, the capacitor C9, the capacitor C10, the capacitor C11, and the capacitor C12. In the present embodiment, the filter F12 is a high-pass filter.

The inductor L1 includes the first inductor 15. The inductor L2 includes the second inductor 16. The inductor L3 includes the third inductor 17. The inductor L4 includes the fourth inductor 18.

The filter F21 includes the inductor L5, the inductor L6, the capacitor C13, the capacitor C14, the capacitor C15, the capacitor C16, the capacitor C17, the capacitor C18, the capacitor C19, and the capacitor C20. In the present embodiment, the filter F21 is a high-pass filter. The filter F22 includes the inductor L7, the inductor L8, the capacitor C21, the capacitor C22, the capacitor C23, the capacitor C24, and the capacitor C25. In the present embodiment, the filter F22 is a low-pass filter.

The inductor L5 includes the fifth inductor 19. The inductor L6 includes the sixth inductor 20. The inductor L7 includes the seventh inductor 21. The inductor L8 includes the eighth inductor 22.

As described above, the electronic component 1 according to the present embodiment includes the first shield 50 and the second shield 51. The first shield 50 is disposed between the fourth inductor 18 and the seventh inductor 21 and extends in the third direction D3. Thus, in the electronic component 1, isolation between the fourth inductor 18 (first filter F1) and the seventh inductor 21 (second filter F2) can be secured. Further, in the electronic component 1, the second shield 51 extends in the first direction D1 and is disposed in the region outside the first inductor group IG1 when viewed from the second direction D2. Thus, in the electronic component 1, the second shield 51 can suppress wraparound of the magnetic flux between the fourth inductor 18 and the seventh inductor 21. Therefore, in the electronic component 1, the isolation between the first filter F1 and the second filter F2 can be improved. As a result, characteristics of the electronic component 1 can be improved.

In the electronic component 1 according to the present embodiment, the first shield 50 and the second shield 51 are connected to each other. In this configuration, the isolation between the first filter F1 and the second filter F2 can be further improved.

In the electronic component 1 according to the present embodiment, the axial direction of the fourth inductor 18 and the axial direction of the seventh inductor 21 intersect each other when viewed from the second direction D2. In this configuration, the wraparound of the magnetic flux can occur between the fourth inductor 18 and the seventh inductor 21. Therefore, in a configuration in which the axial direction of the fourth inductor 18 and the axial direction of the seventh inductor 21 intersect each other, it is particularly effective to provide the second shield 51 for improving the isolation.

In the electronic component 1 according to the present embodiment, the axial direction of the seventh inductor 21 intersects the extending direction of the first shield 50 when viewed from the second direction D2. In the electronic component 1, the axial direction of the fourth inductor 18 intersects the extending direction of the second shield 51. In this configuration, the isolation between the first filter F1 and the second filter F2 can be improved.

In the electronic component 1 according to the present embodiment, the second shield 51 extends along the side surface 2e of the element body 2. In this configuration, the wraparound of the magnetic flux can be effectively suppressed.

In the electronic component 1 according to the present embodiment, the second shield 51 overlaps a part of the fourth inductor 18 when viewed from the third direction D3. In this configuration, the wraparound of the magnetic flux can be effectively suppressed.

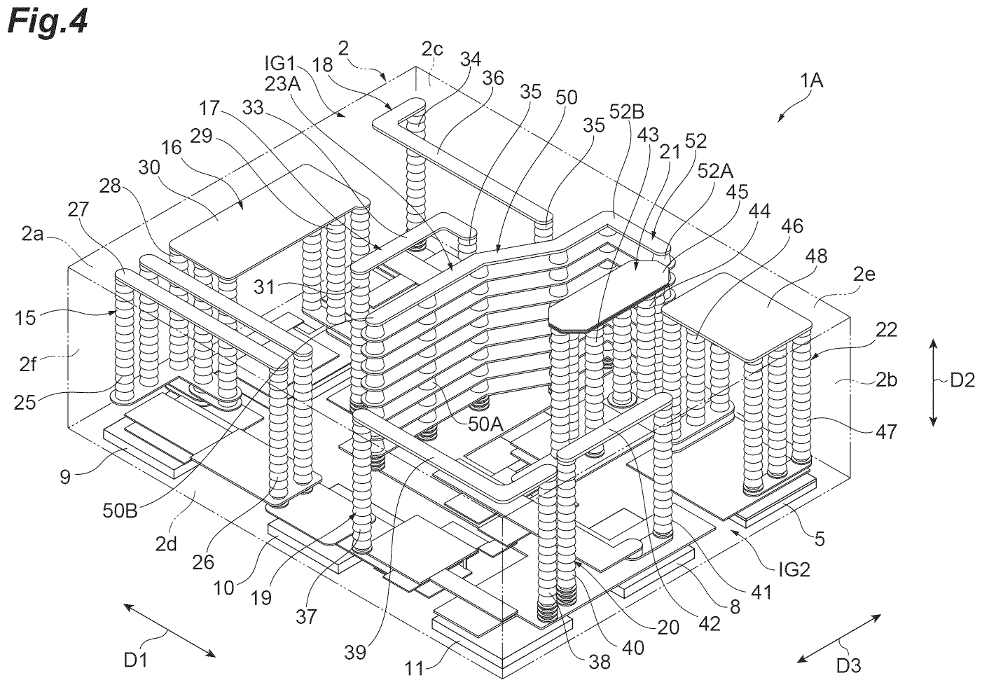

In the electronic component 1 according to the present embodiment, heights of the first shield 50 and the second shield 51 in the second direction D2 are the same as that of the fourth inductor 18 in the lamination direction. In this configuration, the isolation between the first filter F1 and the second filter F2 can be further improved.

[Second Embodiment] Subsequently, a second embodiment will be described. FIG. 4 is a perspective view illustrating the electronic component according to the second embodiment. As illustrated in FIG. 4, in an electronic component 1A, the first inductor 15, the second inductor 16, the third inductor 17, the fourth inductor 18, the fifth inductor 19, the sixth inductor 20, the seventh inductor 21, the eighth inductor 22, and a shield 23A are arranged in the element body 2.

The shield 23A shields the magnetic flux between the first inductor group IG1 and the second inductor group IG2. The shield 23A is electrically connected to the second terminal electrode 4, the fifth terminal electrode 7, the sixth terminal electrode 8, and the ninth terminal electrode 11. A height of the shield 23A in the second direction D2 is the same as that of the first inductor 15, the second inductor 16, the third inductor 17, the fourth inductor 18, the fifth inductor 19, the sixth inductor 20, the seventh inductor 21, and the eighth inductor 22 in the second direction D2. That is, a height position of an end of the shield 23A on the main surface 2c side is the same as that of an end of each of the first inductor 15, the second inductor 16, the third inductor 17, the fourth inductor 18, the fifth inductor 19, the sixth inductor 20, the seventh inductor 21, and the eighth inductor 22 on the main surface 2c side.

The shield 23A is configured by including the first shield 50 and a second shield 52. In the present embodiment, the first shield 50 and the second shield 52 are electrically connected and integrally formed.

The second shield 52 is connected to one end (end on the side surface 2e side) of the first shield 50. The second shield 52 is disposed in a region outside the second inductor group IG2. The second shield 52 is disposed between the side surface 2e of the element body 2 and the seventh inductor 21. The second shield 52 is disposed at a position overlapping a part of the seventh inductor 21 when viewed from the third direction D3. The second shield 52 extends in the first direction D1. An extending direction of the second shield 52 is orthogonal to (intersects) the axial direction of the fourth inductor 18.

The second shield 52 is configured by including a second conductor 52A and a plurality of second connection conductors 52B. In the present embodiment, one second conductor 52A is provided. The second conductor 52A extends in the second direction D2. The second conductor 52A can include a plurality of via conductors.

In the present embodiment, a second connection conductor 52B is formed integrally with the first connection conductor 50B. Nine second connection conductors 52B are provided. The plurality of second connection conductors 52B have the same configuration and the same dimension. Each of the plurality of second connection conductors 52B electrically connects the second conductor 52A and the first conductor 50A.

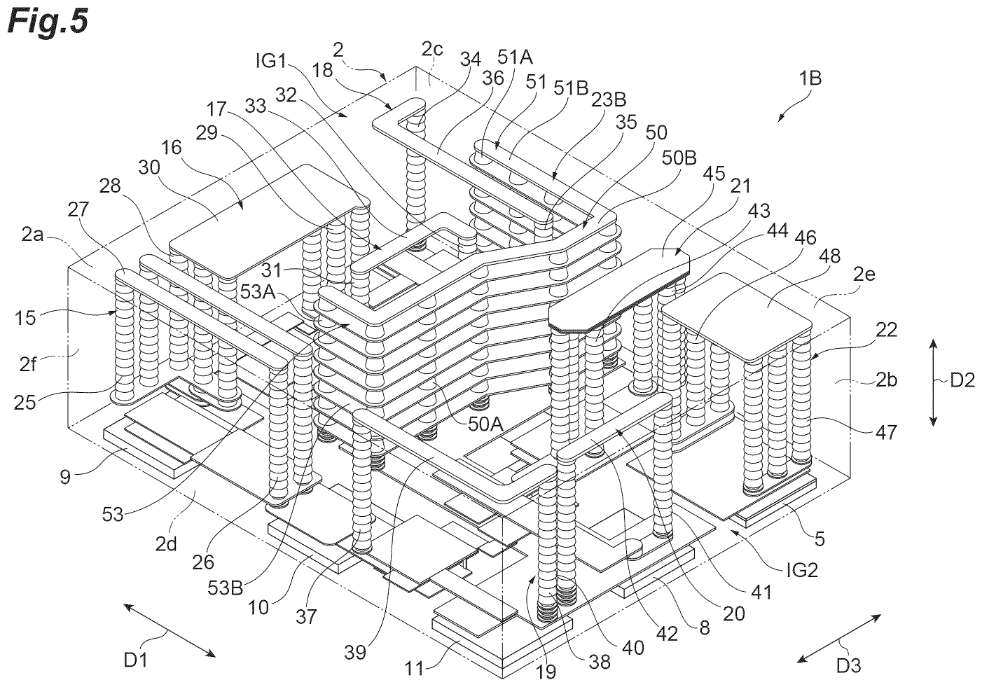

As described above, the electronic component 1A according to the present embodiment includes the first shield 50 and the second shield 52. The first shield 50 is disposed between the fourth inductor 18 and the seventh inductor 21 and extends in the third direction D3. Thus, in the electronic component 1A, the isolation between the fourth inductor 18 (first filter F1) and the seventh inductor 21 (second filter F2) can be secured. Further, in the electronic component 1A, the second shield 52 extends in the first direction D1 and is disposed in a region outside the second inductor group IG2 as viewed from the second direction D2. Thus, in the electronic component 1A, the second shield 52 can suppress the wraparound of the magnetic flux between the fourth inductor 18 and the seventh inductor 21. Therefore, in the electronic component 1A, the isolation between the first filter F1 and the second filter F2 can be improved. As a result, characteristics of the electronic component 1A can be improved.

[Third Embodiment] Subsequently, a third embodiment will be described. FIG. 5 is a perspective view illustrating the electronic component according to the third embodiment. As illustrated in FIG. 5, in an electronic component 1B, the first inductor 15, the second inductor 16, the third inductor 17, the fourth inductor 18, the fifth inductor 19, the sixth inductor 20, the seventh inductor 21, the eighth inductor 22, and a shield 23B are arranged in the element body 2.

The shield 23B is configured by including the first shield 50, the second shield 51, and a third shield 53. In the present embodiment, the first shield 50, the second shield 51, and the third shield 53 are electrically connected and integrally formed.

The third shield 53 is connected to the other end (end on the side surface 2f side) of the first shield 50. The third shield 53 is disposed in a region of the first inductor group IG1. The third shield 53 is disposed between the first inductor 15 and the third inductor 17 in the third direction D3. The third shield 53 is disposed at a position overlapping a part of the first inductor 15 and the third inductor 17 when viewed from the third direction D3. The third shield 53 extends in the first direction D1.

The third shield 53 is configured by including a third conductor 53A and a plurality of third connection conductors 53B. In the present embodiment, one third conductor 53A is provided. A plurality of the third conductors 53A have the same configuration and the same dimension. The third conductor 53A extends in the second direction D2. Each of the third conductors 53A can include a plurality of via conductors.

In the present embodiment, a third connection conductor 53B is formed integrally with the first connection conductor 50B. Nine third connection conductors 53B are provided. The plurality of third connection conductors 53B have the same configuration and the same dimension. Each of the plurality of third connection conductors 53B electrically connects the first conductor 50A and the third conductor 53A.

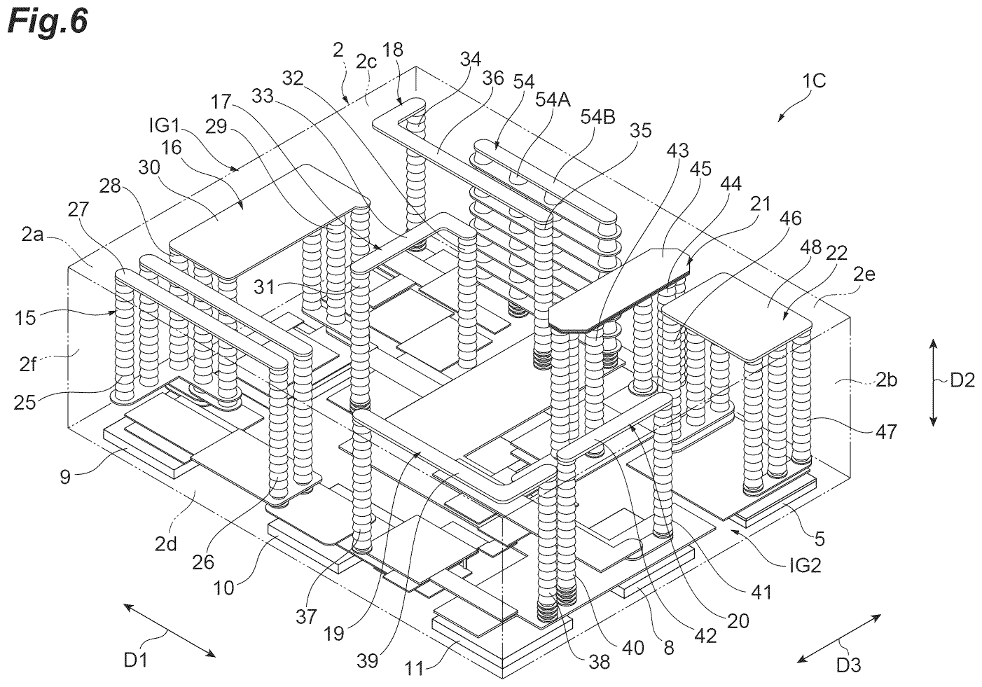

As described above, the electronic component 1B according to the present embodiment includes the first shield 50, the second shield 51, and the third shield 53. The first shield 50 is disposed between the fourth inductor 18 and the seventh inductor 21 and extends in the third direction D3. Thus, in the electronic component 1B, the isolation between the fourth inductor 18 (first filter F1) and the seventh inductor 21 (second filter F2) can be secured. Further, in the electronic component 1B, the second shield 51 extends in the first direction D1 and is disposed in a region outside the first inductor group IG1 as viewed from the second direction D2. Thus, in the electronic component 1B, the second shield 51 can suppress the wraparound of the magnetic flux between the fourth inductor 18 and the seventh inductor 21. Therefore, in the electronic component 1B, the isolation between the first filter F1 and the second filter F2 can be improved. As a result, characteristics of the electronic component 1B can be improved.

[Fourth Embodiment] Subsequently, a fourth embodiment will be described. FIG. 6 is a perspective view illustrating the electronic component according to the fourth embodiment. As illustrated in FIG. 6, in an electronic component 1C, the first inductor 15, the second inductor 16, the third inductor 17, the fourth inductor 18, the fifth inductor 19, the sixth inductor 20, the seventh inductor 21, the eighth inductor 22, and a shield 54 are arranged in the element body 2.

The shield 54 is disposed in the region outside the first inductor group IG1. The shield 54 is disposed between the side surface 2e of the element body 2 and the fourth inductor 18. The shield 54 is disposed at a position overlapping a part of the fourth inductor 18 when viewed from the third direction D3. The shield 54 extends in the first direction D1. An extending direction of the shield 54 is orthogonal to (intersects) the axial direction of the fourth inductor 18.

The shield 54 is configured by including a plurality of conductors 54A and a plurality of connection conductors 54B. In the present embodiment, four conductors 54A are provided. The plurality of conductors 54A have the same configuration and the same dimension. Each of the plurality of conductors 54A extends in the second direction D2. Each of the plurality of conductors 54A can include a plurality of via conductors. The plurality of conductors 54A are arranged at predetermined intervals.

In the present embodiment, nine connection conductors 54B are provided. The plurality of connection conductors 54B have the same configuration and the same dimension. Each of the plurality of connection conductors 54B electrically connects the conductors 54A. The plurality of connection conductors 54B are arranged at predetermined intervals in the second direction D2. The plurality of connection conductors 54B have a predetermined width when viewed from the second direction D2.

As described above, the electronic component 1C according to the present embodiment includes the shield 54. The shield 54 extends in the first direction D1, and extends in the first direction D1 in which the first inductor group IG1 and the second inductor group IG2 are arranged when viewed from the second direction D2. Thus, in the electronic component 1C, the shield 54 can suppress the wraparound of the magnetic flux between the fourth inductor 18 and the seventh inductor 21. Therefore, in the electronic component 1C, the isolation between the first filter F1 and the second filter F2 can be improved. As a result, characteristics of the electronic component 1C can be improved.

Although the embodiments of the present disclosure have been described above, the present disclosure is not necessarily limited to the above-described embodiments, and various modifications can be made without departing from the gist thereof.

In the first embodiment, a mode in which the heights of the first shield 50 and the second shield 51 in the second direction D2 are the same as that of the fourth inductor 18 in the lamination direction has been described as an example. However, the heights of the first shield 50 and the second shield 51 in the second direction D2 may be different from that of the fourth inductor 18 in the lamination direction. From the viewpoint of securing isolation, the heights of the first shield 50 and the second shield 51 in the second direction D2 are preferably equal to or higher than that of the fourth inductor 18 in the lamination direction. The same applies to the second embodiment, the third embodiment, and the fourth embodiment.

In the first embodiment, a mode in which the first shield 50 includes the first conductor 50A and the first connection conductor 50B has been described as an example. However, the first shield may include only the first conductor. In addition, the first shield may be configured by arranging a plurality of first conductors adjacent to (in contact with) each other. The same applies to the second shield. The shield only needs to have a function of shielding the magnetic flux, and a shape and the like of the shield are not limited. For example, the shield may have a plate shape (wall shape).

In the first embodiment, a mode in which the first shield 50 and the second shield 51 are connected in the shield 23 has been described as an example. However, the first shield 50 and the second shield 51 may be separated (may be provided independently of each other). The same applies to the second embodiment and the third embodiment.

In the first embodiment, a mode in which the second shield 51 is disposed in the region outside the first inductor group IG1 has been described as an example. However, the second shield 51 may be disposed over a region where the first inductor group IG1 is disposed and a region where the second inductor group IG2 is disposed. That is, the shield 23 may have a T-shape when viewed from the second direction D2. The same applies to the shield 23B of the third embodiment. Further, the shield 54 according to the fourth embodiment may also be disposed over the region where the first inductor group IG1 is disposed and the region where the second inductor group IG2 is disposed.

In the first embodiment, a mode in which the second shield 51 is connected to one end of the first shield 50 in the shield 23 has been described as an example. However, the second shield 51 only needs to be connected to the first shield 50, and may be connected to a side portion in the extending direction of the first shield 50. The shield 23 may have a cross shape when viewed from the second direction D2.

What is claimed is:

1. An electronic component comprising:
an element body formed by laminating a plurality of insulator layers;
a first conductor group including a first inductor constituting a first filter having a first pass band;
a second conductor group including a second inductor constituting a second filter having a second pass band;
a first shield disposed between the first inductor and the second inductor when viewed from a lamination direction of the plurality of insulator layers and extending in another direction orthogonal to one direction in which the first conductor group and the second conductor group are arranged; and
a second shield extending in the one direction, wherein
the second shield is disposed in a region outside the first conductor group when viewed from the lamination direction.

2. The electronic component according to claim 1, wherein the first shield and the second shield are connected to each other.

3. The electronic component according to claim 1, wherein an axial direction of the first inductor and an axial direction of the second inductor intersect each other when viewed from the lamination direction.

4. The electronic component according to claim 3, wherein the axial direction of the second inductor intersects an extending direction of the first shield when viewed from the lamination direction.

5. The electronic component according to claim 4, wherein the axial direction of the first inductor intersects an extending direction of the second shield when viewed from the lamination direction.

6. The electronic component according to claim 1, wherein the second shield extends along an outer surface of the element body.

7. The electronic component according to claim 1, wherein the second shield overlaps at least a part of the first inductor or the second inductor when viewed from the other direction.

8. The electronic component according to claim 1, wherein heights of the first shield and the second shield in the lamination direction are the same as a height of the first inductor in the lamination direction.

9. An electronic component comprising:
an element body formed by laminating a plurality of insulator layers;
a first conductor group including a first inductor constituting a first filter having a first pass band;
a second conductor group including a second inductor constituting a second filter having a second pass band; and
a shield extending in one direction in which the first conductor group and the second conductor group are arranged when viewed from a lamination direction of the plurality of insulator layers.

10. The electronic component according to claim 9, wherein
each of the first inductor and the second inductor is disposed at a position close to one side surface of the element body, and
the shield is disposed between the first inductor and the one side surface.

11. The electronic component according to claim 9, wherein an axial direction of the first inductor and an axial direction of the second inductor intersect each other.

12. The electronic component according to claim 11, wherein the axial direction of the first inductor intersects an extending direction of the shield.

13. The electronic component according to claim 9, wherein the shield overlaps at least a part of the first inductor or the second inductor when viewed from another direction orthogonal to the one direction in which the first conductor group and the second conductor group are arranged.

14. The electronic component according to claim 9, wherein the shield is disposed over a region where the first conductor group is disposed and a region where the second conductor group is disposed.
